(19) United States
(12) Patent Application Publication
(10) Pub. No.: US 2014/0054753 A1
(43) Pub. Date: Feb. 27, 2014

(54) NANO-MESHED STRUCTURE PATTERN ON SAPPHIRE SUBSTRATE BY METAL SELF-ARRANGEMENT

(71) Applicant: National Central University, Jhongli City (TW)

(72) Inventors: Cheng-Yi LIU, Jungli City (TW); Cheng-Chieh CHANG, Kaohsiung City (TW)

(21) Appl. No.: 13/943,122

(22) Filed: Jul. 16, 2013

(30) Foreign Application Priority Data
Aug. 23, 2012 (TW) 101130591

(51) Int. Cl. H01L 21/308

(52) U.S. Cl. CPC H01L 21/3083
USPC 257/623; 438/694

(57) ABSTRACT

The present disclosure provides a nano-meshed patterned substrate and a method of forming the same. In an embodiment, a metal layer is formed on a substrate, and a heat treatment is performed on the substrate and the metal layer so that the metal layer is transformed into a nano-meshed metal structure. The substrate is then etched using the nano-meshed metal structure as an etch mask. After removing the nano-meshed metal structure, a nano-meshed patterned substrate is obtained.

### CROSS REFERENCE TO RELATED APPLICATIONS

This application claims priority of Taiwan Patent Application No. 101130591, filed on Aug. 23, 2012, the entirety of which is incorporated by reference herein.

### BACKGROUND OF THE INVENTION

1. Field of the Invention

The present invention relates to a patterned substrate, and in particular, relates to a nano-scale patterned substrate and the method of forming the same.

2. Description of the Related Art

Light-emitting diodes (LED) have been widely utilized in various applications, for example, as backlight modules for liquid crystal displays (LCDs), and light sources for use in vehicles, traffic lights, and general illumination devices, due to their small size, fast response, low driving voltage/current, long lifetime, low thermal radiation, high mass production efficiency, and low energy consumption. In recent years, various technologies have been developed to enhance the luminous efficiency of light-emitting diodes, including the patterned sapphire substrates (PSS) technology. Through the patterned surface of a substrate, the light emitted from the active layer of the light emitting diode can be scattered, and the total reflection occurring in the light emitting diode can be reduced. Therefore, the light-extraction efficiency (LEE) and the external quantum efficiency (EQE) of the light emitting diode can be enhanced, and the defects occurring in the epitaxial layers of the light emitting diode can be reduced.

The pattern size of the conventional patterned sapphire substrates is usually manufactured at micro-scale due to the resolution limit of conventional lithography processes. Further reduction of the pattern size (for example, to obtain a pattern size at nano-scale) may be achieved, for example, by using ion-beam direct writing technology, which may provide a pattern on the surface of the substrate directly. However, due to the disadvantages of the ion-beam direct writing technology, such as having a complex, high-cost, and time-consuming manufacturing process, the ion-beam direct writing technology is not very suitable for mass production. Accordingly, a nano-scale patterned substrate technology with a simple manufacturing process and low cost to provide improved light extraction efficiency, external quantum efficiency, and luminous efficiency of light emitting diodes is desired.

### BRIEF SUMMARY OF THE INVENTION

A detailed description is given in the following embodiments with reference to the accompanying drawings.

One of the broader forms of the present disclosure involves a method of forming a nano-pattern, comprising: forming a metal layer on a substrate; performing a heat treatment on the substrate with the metal layer formed thereon to form a nano-meshed metal structure on the substrate; etching the substrate using the nano-meshed metal structure as an etch mask; and removing the nano-meshed metal structure to obtain a nano-patterned substrate with a nano-meshed pattern.

Another one of the broader forms of the present disclosure involves a nano-patterned substrate, wherein a surface of the substrate has a nano-scale protrusion, and the nano-scale protrusion has a continuous and irregular meshed structure.

### BRIEF DESCRIPTION OF THE DRAWINGS

The present invention can be more fully understood by reading the subsequent detailed description and examples with references made to the accompanying drawings, wherein:

FIGS. 1A-1D illustrate a series of cross-sectional views of an embodiment of a method of forming a nano-scale patterned substrate at different steps according to the present invention.

FIG. 2 illustrates a plan view of an embodiment of a nano-meshed metal structure formed on a substrate according to the present invention.

FIG. 3 shows a picture of the plan view of the surface morphology of a patterned substrate of an embodiment of the present invention using a scanning electron microscope.

FIG. 4 shows a picture of the plan view of the surface morphology of a patterned substrate of another embodiment of the present invention using a scanning electron microscope.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

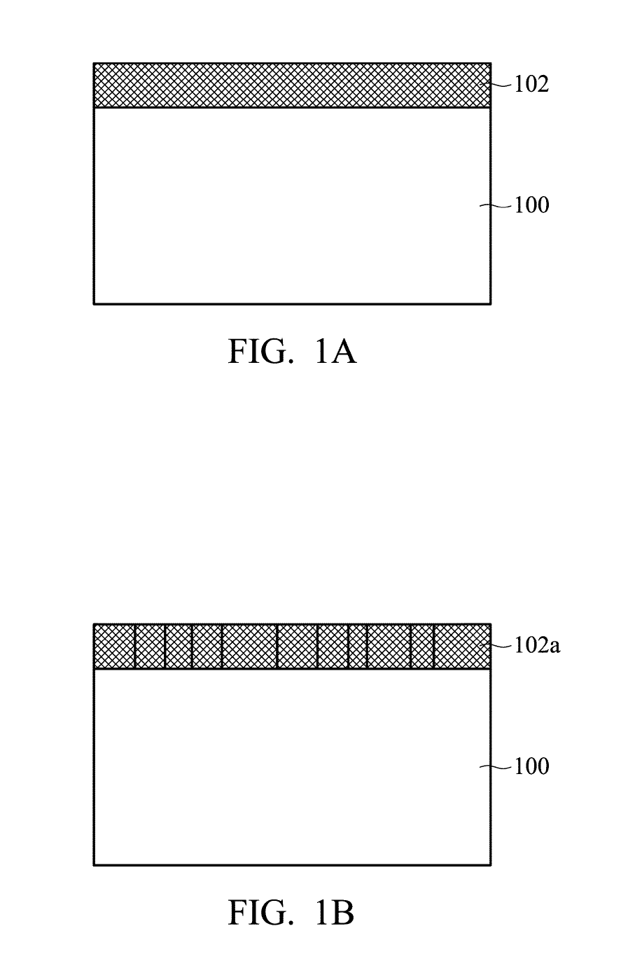

The present invention provides a nano-scale patterned substrate and a method of forming the same. FIGS. 1A-1D illustrate a series of cross-sectional views of an embodiment of a method of forming a nano-scale patterned substrate at different steps provided by the present invention. At the step illustrated in FIG. 1A, a substrate 100 is provided. The substrate 100 has a hexagonal or cubic crystal structure. The substrate 100 may comprise sapphire, gallium arsenide (GaAs), indium phosphide (InP), gallium nitride (GaN), aluminum gallium nitride (AlGaN), aluminum nitride (AlN), indium gallium nitride (GaInN), indium nitride (InN), gallium indium arsenic nitride (GaInAsN), silicon carbide (SiC), zinc oxide (ZnO), aluminum zinc oxide (AZO), or the combinations thereof. In an embodiment, the substrate 100 is a sapphire substrate. A metal layer 102 is then formed on the substrate 100. The thickness of the metal layer 102 may be in a range of about 1 angstrom (Å) to 1000 angstroms. In another embodiment, the thickness of the metal layer 102 may be in a range of about 50 nm to 500 nm. The metal layer 102 may be a monolayer or a multilayer structure. The metal layer 102 may be formed by any suitable process, such as physical vapor deposition (PVD), chemical vapor deposition (CVD), or electroplating process. In an embodiment, the metal layer 102 is a platinum (Pt) metal layer with a thickness of about 50 angstroms to 500 angstroms.

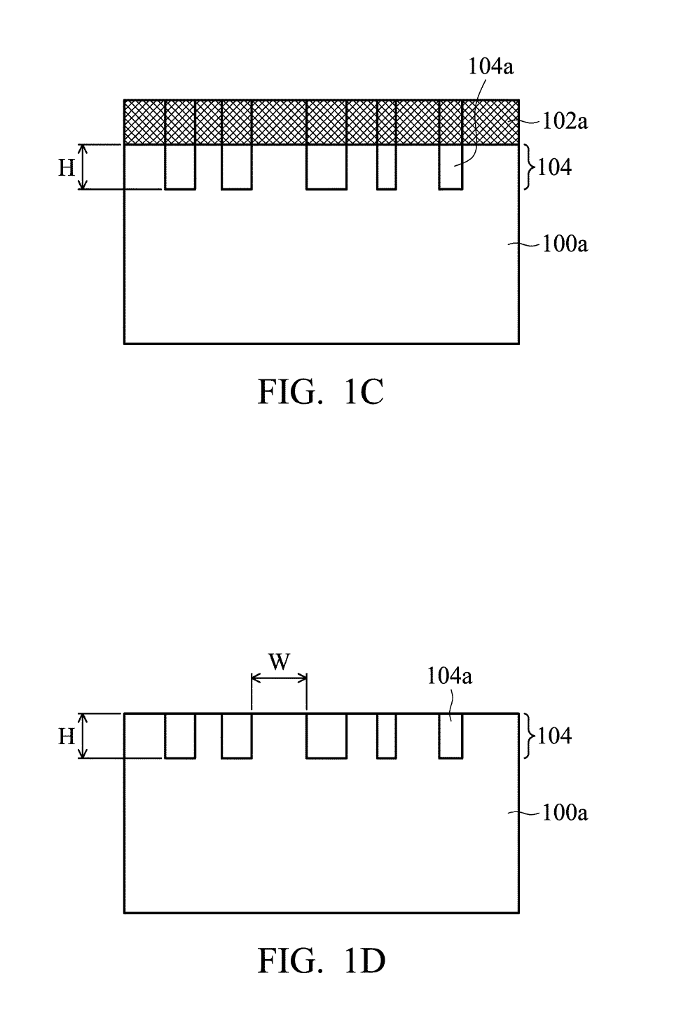

Next, a heat treatment is performed on the substrate 100 with the metal layer 102 formed thereon. The heat treatment temperature may be in a range of about 500° C. to 900° C. In another embodiment, the heat treatment temperature is in a range of about 600° C. to 700° C. The heat treatment time may be less than 60 minutes. In another embodiment, the heat treatment time is less than 10 minutes. The heat treatment may be performed under an ambient atmosphere, which comprises nitrogen, oxygen, argon, or the combinations thereof. In an embodiment, nitrogen gas is used as the ambient atmosphere of the heat treatment to reduce costs and to shorten the heat treatment time. In this embodiment, since the crystal structure of the sapphire substrate 100 is similar to that of the platinum metal layer 102, the platinum metal layer 102 may demonstrate a self-arranging behavior under the high temperature condition of the heat treatment. That is, the platinum atoms in the platinum metal layer 102 may be arranged along (0001) planes of the sapphire substrate 100, thereby providing a continuous and irregular meshed structure 102a, as illustrated in FIG. 1B and FIG. 2. FIG. 2 illustrates a plan view of an embodiment of the nano-meshed metal structure 102a formed on the substrate 100 according to the present invention. FIG. 1B illustrates a cross-sectional view along the A-A′ line in FIG. 2. The nano-meshed metal structure 102a comprises a plurality of lines interleaving with each other and a plurality of openings exposing the substrate 100. In the present invention, various nano-meshed metal structures 102a may be obtained by controlling the heat treatment temperature and the heat treatment time. When the heat treatment temperature is in a range of about 500° C. to about 900° C. and the heat treatment time is less than 60 minutes, the higher the heat treatment temperature or the longer the heat treatment time, the narrower the width of each line of the nano-meshed metal structure 102a and the lower the coverage percentage of the nano-meshed metal structure 102a. When the metal layer 102 is constituted by a multilayer structure, a nano-meshed metal structure with a different coverage percentage, size, or shape may be obtained under the same heat treatment conditions, according to the inter-metallic diffusion (promoting or inhibiting) between the different metal layers. For example, in the case of the metal layer constituted by a multilayer structure using a metal material inhibiting the diffusion of platinum atoms, the nano-meshed metal structure 102a will not be formed even under the above heat treatment condition. When the heat treatment temperature is in a range of about 500° C. to 900° C. and the heat treatment time is greater than 60 minutes, or the heat treatment temperature is greater than about 900° C., the metal layer 102 is transformed into a plurality of columnar metal structures, rather than a meshed structure on the surface of the substrate.

Next, the exposed regions of the substrate 100 are etched using the nano-meshed metal structure 102a as an etch mask to form a nano-scale meshed pattern 104 with a plurality of openings 104a, as illustrated in FIG. 1C. The etching depth of the substrate 100 (i.e. the height H of the nano-scale meshed pattern 104) may be in a range of about 1 nm to 1000 nm. In another embodiment, the etching depth of the substrate 100 is in a range of about 50 nm to 500 nm. The etching step may be a wet etching step using an acid solution as an etching solution, for example, a sulfuric acid solution or a mixed solution of sulfuric acid and phosphoric acid. In an embodiment, a pure sulfuric acid is used as the etching solution. The solution temperature may be in a range of 220° C. to 380° C., and the etching time may be in a range of 60 to 1200 seconds. In another embodiment, the solution temperature may be in a range of 240° C. to 300° C., and the etching time may be in a range of 300 to 600 seconds. Alternatively, the etching step may be a dry etching step using an etching gas, for example, an etching gas comprising carbon tetrachloride, hydrogen bromide, boron trichloride, argon, chlorine, oxygen, and methane. It is noted that those skilled in the art of the present invention may change the heat treatment temperature and time at the step illustrated in FIG. 1B without departing from the scope of the present invention to obtain various nano-meshed metal structures 102a (for example, various nano-meshed metal structures 102a with different coverage percentages) and then control the etching recipes at the step illustrated in FIG. 1C, such as the composition ratio of the etching solution, the temperature of the etching solution, and the etching time of the etching solution, to obtain various nano-scaled meshed patterns 104 with different coverage percentages, sizes and shapes.

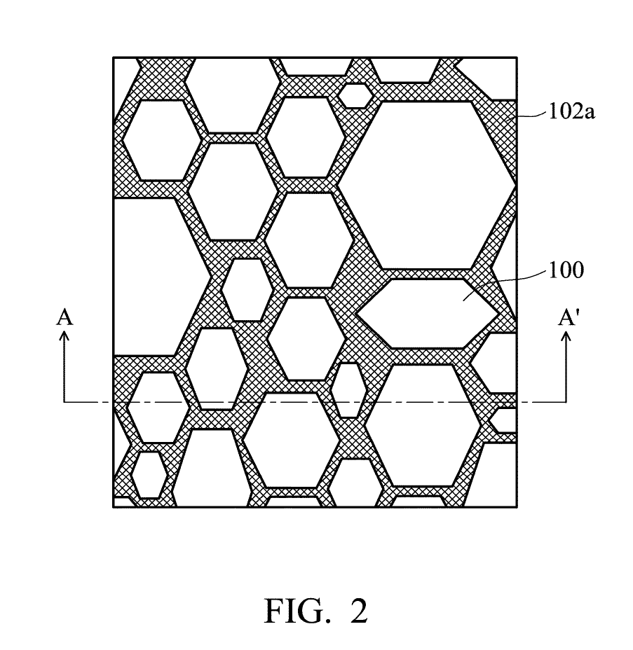

The nano-meshed metal structure 102a is then removed to obtain a nano-meshed patterned substrate 100a with the nano-scale meshed pattern 104, as FIG. 1D illustrates. Any suitable physical or chemical methods, such as a wet etching process with aqua regia or an ion bombardment process, may be used to remove the nano-meshed metal structure 102a to obtain the nano-meshed patterned substrate 100a. FIG. 3 shows a picture of the plan view of a patterned substrate of an embodiment provided by the present invention using a scanning electron microscope (SEM). The nano-meshed patterned substrate 100a has a nano-scale protrusion at its surface, which is formed by a wet etching process using the nano-meshed metal structure 102a as an etch mask. Compared with the regular patterns formed by the conventional lithography and etching processes, the nano-scale protrusion formed by the method according to the present invention has a continuous and irregular meshed structure. The height H of the nano-scale protrusion may be in a range of about 1 nm to 1000 nm. In another embodiment, the height H of the nano-scale protrusion is in a range of about 50 nm to 500 nm. The width W of each lines of the nano-scale protrusion may be in a range of about 1 nm to 1000 nm. In another embodiment, the width W of each lines of the nano-scale protrusion may be in a range of about 70 nm to 300 nm. The nano-scale protrusion constitutes the nano-scale meshed pattern 104 with a plurality of openings 104a of the present invention. In an embodiment, the coverage percentage of the nano-scale meshed pattern 104 may be in a range of 30 percent to 80 percent. In another embodiment, the coverage percentage of the nano-scale meshed pattern 104 may be in a range of 30 percent to 40 percent.

The present invention may also be applied to the fabrication of a vertical light-emitting diode process. For example, the substrate may be stripped by a laser lift-off (LLO) process after the nano-meshed metal structure is formed on the substrate. Then the nano-meshed metal structure may be transferred onto an n-type GaN substrate. The n-type GaN substrate with the nano-meshed metal structure 102a formed thereon may be wet etched, and a patterned surface may be obtained. Due to the mask-less process according to the present invention, a patterned substrate may be obtained without complex lithography technology, and a nano-scale patterned substrate may be manufactured without a high-cost process such as an ion beam direct writing process. Accordingly, the manufacturing costs can be reduced and the manufacturing process can be simplified. When the nano-scale patterned substrate is applied to the manufacturing of light-emitting devices, it can improve the light extraction efficiency and the quality of the epitaxial layers in the light emitting device, thereby increasing the luminous efficiency of the light emitting device.

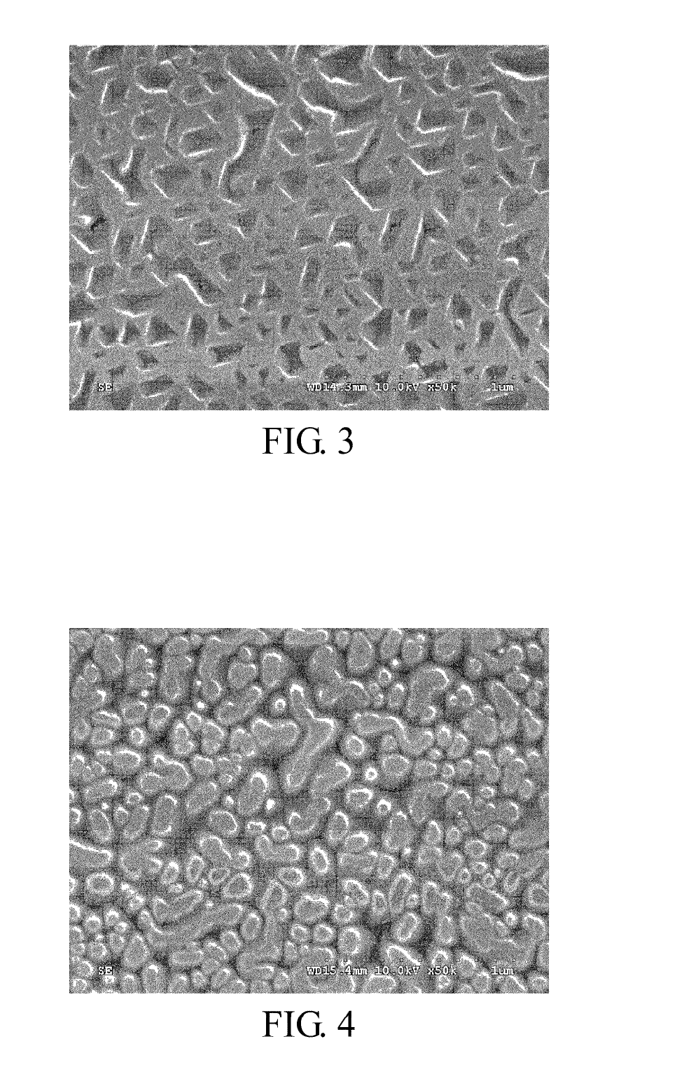

In another embodiment of the present invention, the metal layer 102 may comprise gold, silver, chromium, titanium, nickel, copper, or the combinations thereof, or the heat treatment time may be greater than 60 minutes. Therefore, a plurality of columnar metal structures can be formed on the substrate. The approach of this embodiment is substantially similar to that illustrated in FIGS. 1A-1D. FIG. 4 shows the plan view of the surface morphology of the nano-scale patterned substrate according to this embodiment using a scanning electron microscope. The patterned substrate has a plurality of nano-scale protrusions. The height of each nano-scale protrusion may be in a range of about 5 nm to 1000 nm. In another embodiment, the height of each nano-scale protrusion is in a range of about 20 nm to 80 nm. The diameter of each nano-scale protrusion may be in a range of about 10 nm to 1000 nm. In another embodiment, the diameter of each nano-scale protrusion is in a range of about 70 nm to 250 nm. The nano-scale protrusions are irregularly distributed columnar structures, which constitute the plurality of nano-scale columnar patterns of the present invention.

The present invention comprises utilizing the self-arranging behavior of the metal layer in a high temperature environment to form a nano-scale metal structure on the substrate and etching the substrate using the nano-scale metal structure as an etch mask. After removing the nano-scale metal structure, a nano-scale patterned substrate is obtained. The method according to the present invention may be performed without a high-cost and complex lithography process. Furthermore, a nano-scale patterned substrate with various pattern coverage percentages, sizes, and shapes can be obtained by controlling the process recipe such as the metal layer thickness, metal species, heat treatment temperature, heat treatment time, composition ratio of the etching solution, etching temperature, or etching time.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method of forming a nano-pattern, comprising:
forming a metal layer on a substrate;
performing a heat treatment on the substrate with the metal layer formed thereon to form a nano-meshed metal structure on the substrate;
etching the substrate using the nano-meshed metal structure as an etch mask; and
removing the nano-meshed metal structure to obtain a nano-patterned substrate with a nano-meshed pattern.

2. The method as claimed in claim 1, wherein a height of the nano-meshed pattern is in a range of 1 nm to 1000 nm.

3. The method as claimed in claim 1, wherein a width of each line of the nano-meshed pattern is in a range of 1 nm to 1000 nm.

4. The method as claimed in claim 1, wherein a thickness of the metal layer is in a range of 1 nm to 1000 nm.

5. The method as claimed in claim 1, wherein the metal layer comprises platinum.

6. The method as claimed in claim 1, wherein the substrate has a hexagonal or cubic crystal structure.

7. The method as claimed in claim 1, wherein the substrate comprises sapphire, gallium arsenide, indium phosphide, gallium nitride, aluminum gallium nitride, aluminum nitride, indium gallium nitride, indium nitride, indium gallium arsenic nitride, silicon carbide, zinc oxide, aluminum zinc oxide (AZO), or the combinations thereof.

8. The method as claimed in claim 1, wherein the heat treatment temperature is in a range of 500° C. to 900° C., and the heat treatment time is less than 60 minutes.

9. The method as claimed in claim 1, wherein the heat treatment is performed under an ambient atmosphere comprising nitrogen, oxygen, argon, or the combinations thereof.

10. The method as claimed in claim 1, wherein the etching step comprises a wet etching step or a dry etching step.

11. The method as claimed in claim 10, wherein the wet etching step comprises using a sulfuric acid solution or a mixed solution of sulfuric acid and phosphoric acid as an etching solution.

12. The method as claimed in claim 10, wherein the dry etching step comprises using carbon tetrachloride, hydrogen bromide, boron trichloride, argon, chlorine, oxygen, and methane as an etching gas.

13. A nano-patterned substrate, wherein a surface of the substrate has a nano-scale protrusion, and the nano-scale protrusion has a continuous and irregular meshed structure.

14. The nano-patterned substrate as claimed in claim 13, wherein a height of the nano-scale protrusion is in a range of 1 nm to 1000 nm.

15. The nano-patterned substrate as claimed in claim 13, wherein a width of each line of a top surface of the meshed structure is in a range of 1 nm to 1000 nm.

16. The nano-patterned substrate as claimed in claim 13, wherein the substrate has a hexagonal or cubic crystal structure.

17. The nano-pattern substrate as claimed in claim 13, wherein the substrate comprises sapphire, gallium arsenide, indium phosphide, gallium nitride, aluminum gallium nitride, aluminum nitride, indium gallium nitride, indium nitride, indium gallium arsenic nitride, silicon carbide, zinc oxide, aluminum zinc oxide (AZO), or the combinations thereof.
